(19) United States
(12) Patent Application Publication
(10) Pub. No.: US 2025/0336450 A1
(43) Pub. Date: Oct. 30, 2025

(54) MEMORY DEVICE AND METHOD OF OPERATING THE MEMORY DEVICE

(71) Applicant: Samsung Electronics Co., Ltd., Suwon-si (KR)

(72) Inventor: Daeshik KIM, Suwon-si (KR)

(73) Assignee: Samsung Electronics Co., Ltd., Suwon-si (KR)

(21) Appl. No.: 19/188,534

(22) Filed: Apr. 24, 2025

(30) Foreign Application Priority Data
Apr. 30, 2024 (KR) 10-2024-0058128

(51) Int. Cl. G11C 16/28; G11C 16/08; G11C 16/32; G11C 17/02

(52) U.S. Cl. CPC G11C 16/28; G11C 16/08; G11C 16/32; G11C 17/02

(57) ABSTRACT

Provided is a memory device configured to control such that a first electrical signal is applied to the normal memory cell during a read operation of the normal memory cell and a second electrical signal having a magnitude greater than that of the first electrical signal is applied to the OTP memory cell during a read operation of the OTP memory cell, a read driver configured to provide the first electrical signal to the normal memory cell and the second electrical signal to the OTP memory cell based on the control signal, and a sense amplifier configured to detect a first input signal applied from the normal memory cell based on the first electrical signal and detect a second input signal applied from the OTP memory cell based on the second electrical signal.

### CROSS-REFERENCE TO RELATED APPLICATION

This application is based on and claims priority under 35 U.S.C. § 119 to Korean Patent Application No. 10-2024-0058128, filed on Apr. 30, 2024, in the Korean Intellectual Property Office, the disclosure of which is incorporated by reference herein in its entirety.

### BACKGROUND

The inventive concepts relate to memory devices and methods of operating the memory device, and more particularly, to memory devices that improve the read margin of a one-time programmable (OTP) memory cell and methods of operating the memory device.

A resistive memory device is capable of storing data in memory cells that include variable resistance elements. A variable resistance element may include a magnetic tunnel junction (MTJ) element. For example, an MTJ element may include two magnetic materials and an insulation film provided therebetween. The resistance value of the MTJ element may vary depending on the magnetization directions of the two magnetic materials. For example, when the magnetization directions of the two magnetic materials are anti-parallel with each other, the MTJ device may have a large resistance value, and, when the magnetization directions of the two magnetic materials are parallel with each other, the MTJ device may have a small resistance value. Data may be programmed and read out using difference between resistance values.

A resistive memory device includes a normal memory cell and an OTP memory cell, and the normal memory cell and the OTP memory cell may each include a variable resistance element. A normal memory cell may store data or read stored data by using a variable resistance element. An OTP memory cell may be programed only once. Once programmed, data programmed thereto is unchangeable and may be retained even after power supply is removed.

An OPT memory cell may be used for security-critical data, such as memory device settings. An OTP memory cell may store security-critical data, and errors need to be minimized when reading data from an OTP memory cell. Therefore, technology for improving the read margin of an OTP memory cell is demanded.

### SUMMARY

The inventive concepts provide memory devices and methods of operating the same for improving the read margin of a one-time programmable (OTP) memory cell by performing a read operation of the OTP memory cell using a reference resistance value to distinguish between a breakdown state and an anti-parallel state of the OTP memory cell.

According to an example embodiment of the inventive concepts, a memory device including includes a cell array including a normal memory cell and a one-time programmable (OTP) memory cell, the normal memory cell configured to be programmable a plurality of number of times, an OTP memory cell configured to be programmable once, a controller configured to control such that a first electrical signal is applied to the normal memory cell during a read operation of the normal memory cell and a second electrical is applied to the OTP memory cell during a read operation of the OTP memory cell, a read driver configured to provide the first electrical signal to the normal memory cell and the second electrical signal to the OTP memory cell based on a control signal from the controller, and a sense amplifier configured to detect a first input signal applied from the normal memory cell based on the first electrical signal and detect a second input signal applied from the OTP memory cell based on the second electrical signal, wherein a magnitude of the second electrical signal is greater than a magnitude of the first electrical signal.

According to an example embodiment of the inventive concepts, a memory device includes a normal memory cell configured to be programmable a plurality of number of times, an OTP memory cell configured to be programmable once, a normal reference cell having a first reference resistance value to distinguish between a parallel state and an anti-parallel state of the normal memory cell, an OTP reference cell having a second reference resistance value to distinguish between a breakdown state and an anti-parallel state of the OTP memory cell, and a read circuit configured to read data stored in the normal memory cell based on the first reference resistance value during a read operation of the normal memory cell and read data stored in the OTP memory cell based on the second reference resistance value during a read operation of the OTP memory cell.

According to an example embodiment of the inventive concepts, a method of operating a memory device including a normal memory cell configured to be programmable a plurality of number of times and an OTP memory cell configured to be programmable once includes during a read operation of the OTP memory cell, writing data to the OTP memory cell in an anti-parallel state, and reading data stored in the OTP memory cell based on a resistance value to distinguish between a breakdown state and the anti-parallel state of the OTP memory cell.

### BRIEF DESCRIPTION OF THE DRAWINGS

Example embodiments of the inventive concepts will be more clearly understood from the following detailed description taken in conjunction with the accompanying drawings in which:

FIG. 1 is a block diagram showing a memory device according to an example embodiment;

FIG. 2A is a diagram showing an example memory cell according to an example embodiment;

FIG. 2B is a diagram showing an example reference cell according to an example embodiment;

FIG. 3A is a diagram illustrating a cell array according to an example embodiment;

FIG. 3B is a diagram illustrating a cell array according to an example embodiment;

FIG. 4 is a graph showing the distribution and change of resistance values of a variable resistance element included in a normal memory cell, according to an example embodiment;

FIG. 5A is a graph showing the distribution and change of resistance values of a variable resistance element included in a one-time programmable (OTP) memory cell, according to an example embodiment;

FIG. 5B is a graph showing the distribution and change of resistance values of a variable resistance element included in an OTP memory cell, according to an example embodiment;

FIG. 6 is a flowchart of a method of operating a memory device, according to an example embodiment;

FIG. 7A is a block diagram showing a memory device according to an example embodiment;

FIG. 7B is a block diagram showing a memory device according to an example embodiment;

FIG. 8A is a block diagram showing a memory device according to an example embodiment;

FIG. 8B is a block diagram showing a memory device according to an example embodiment;

FIG. 9A is a diagram showing the structure of a memory device during a read operation of a normal memory cell, according to an example embodiment;

FIG. 9B is the structure of a memory device during a read operation of an OTP memory cell, according to an example embodiment;

FIG. 10 is a timing diagram showing an example of the operation of a memory device, according to an example embodiment;

FIG. 11 is a block diagram showing a memory system including a memory device according to an example embodiment; and

FIG. 12 is a block diagram showing a system-on-chip (SoC) including a memory device, according to an example embodiment.

### DETAILED DESCRIPTION

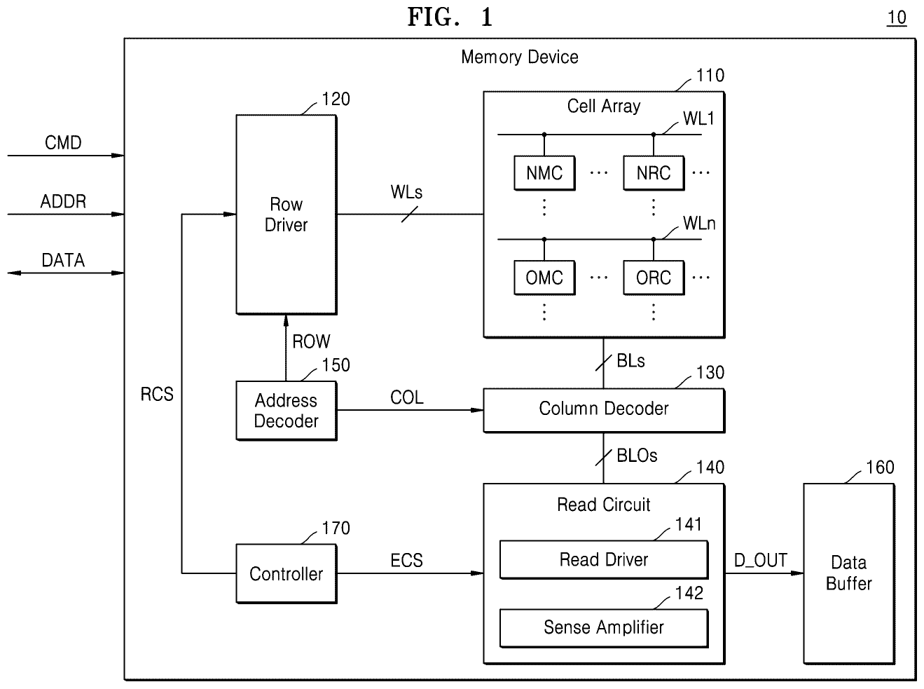

FIG. 1 is a block diagram showing a memory device according to an example embodiment.

Referring to FIG. 1, a memory device 10 may include a cell array 110, a row decoder 120, a column decoder 130, a read circuit 140, an address decoder 150, a data buffer 160, and a controller 170.

The memory device 10 may receive a command CM D and an address ADDR and may receive or output data. For example, the memory device 10 may receive a command CM D such as a write command and a read command and an address ADDR corresponding to the command CM D from a memory controller. Also, the memory device 10 may receive data (e.g., write data) from the memory controller or provide data DATA (e.g., read data) to the memory controller. According to some example embodiments, at least two of a command CM D, an address ADDR, or data DATA may be received or output through the same channel.

The cell array 110 may include a plurality of memory cells (e.g., normal memory cells NMC and one-time programmable (OTP) memory cells OMC. The cell array 110 includes the plurality of memory cells NMC and OMC arranged in rows and columns. The plurality of memory cells NMC and OMC may be connected to a plurality of word lines WLs. Memory cells connected to one word line may be referred to as a page, and data may be read or written page-by-page.

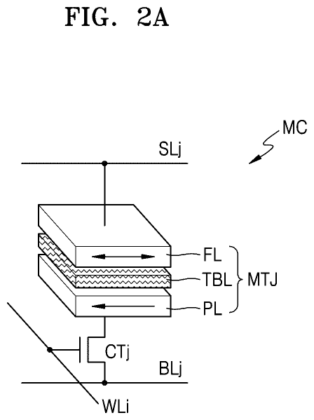

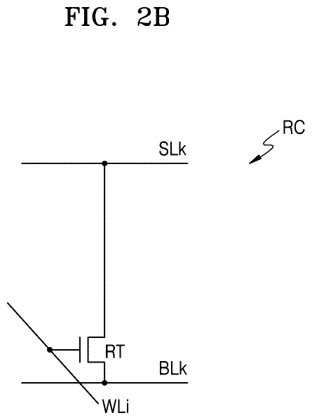

According to some example embodiments, a memory cell may include a variable resistance element (e.g., the MTJ of FIG. 2A), and a variable resistance element MTJ may have a resistance value corresponding to a value (or bits) stored in the memory cell. Hereinafter, a normal memory cell NMC and an OTP memory cell OMC may be referred to as memory cells, and a normal reference cell NRC and an OTP reference cell ORC may be referred to as reference cells. When the memory cells include variable resistance elements MTJ, the memory device 10 may be referred to as a resistive memory device. For example, the memory device 10 may include, but is not limited to, the cell array 110 having the structure of a magnetic random access memory (M RAM) such as spin-transfer torque magnetic random access memory (STT-MRAM), spin torque transfer magnetization switching RAM (Spin-RAM), and spin momentum transfer (SMT-RAM) or may include the cell array 110 having a structure such as phase change random access memory (PRA M) and ferroelectric random access memory (FRAM). Some example embodiments will be mainly described below with reference to M RAM, but example embodiments are not limited thereto.

In the memory device 10, the memory cells NMC and OMC may each include a cell transistor (e.g., a cell transistor CTj of FIG. 2A) and the variable resistance element MTJ. The cell array 110 may include the plurality of word lines WLs, a plurality of bit lines BLs, and a plurality of source lines (e.g., source lines SLj of FIG. 2A) connected to the memory cells NMC and OMC. Each of the word lines WLs may be connected to gates of cell transistors of the memory cells NMC and OMC located in corresponding one of rows of the cell array 110, and each pair of one of the bit lines BLs and a corresponding one of the source lines may be connected to variable resistance elements and sources of cell transistors of the memory cells NMC and OMC located in a corresponding one of columns of the cell array 110.

The memory cell array 110 may include normal memory cells NMC and OTP memory cells OMC. A normal memory cell NMC refers to a memory cell that normally operates to store data and may be programmed a plurality of number of times. An OTP memory cell OMC may refer to a memory cell that operates for an OTP function. An OTP memory cell OMC may be programmed once. According to an example embodiment, the normal memory cell NMC and the OTP memory cell OMC may be implemented as one memory chip, and the memory device 10 may use the normal memory cell NMC and the OTP memory cell OMC simultaneously through one memory chip.

The cell array 110 may include normal memory cells NMC and OTP memory cells OMC connected to different word lines WLs. For example, the normal memory cells NMC may be connected to a word line WL1, and the OTP memory cells OMC may be connected to a word line WLn. Although FIG. 1 shows that the cell array 110 includes one row including the normal memory cells NMC and one row including the OTP memory cells OMC, the inventive concepts are not necessarily limited thereto, and the cell array 110 includes at least one row including the normal memory cells NMC and at least one row including the OTP memory cells OMC. Also, although FIG. 1 shows that the normal memory cell NMC and the OTP memory cell OMC are connected to different word lines WLs and share a bit line BL, the inventive concepts are not necessarily limited thereto, and the normal memory cell NMC and the OTP memory cell OMC may be configured to share the same word line WL.

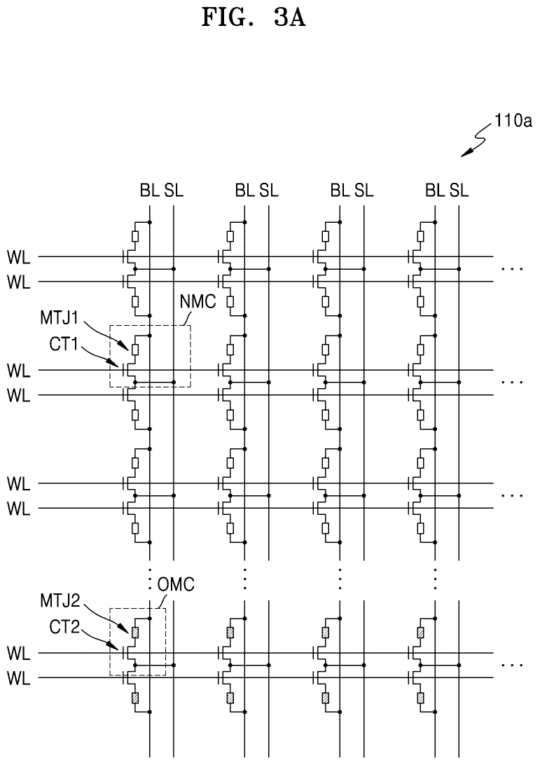

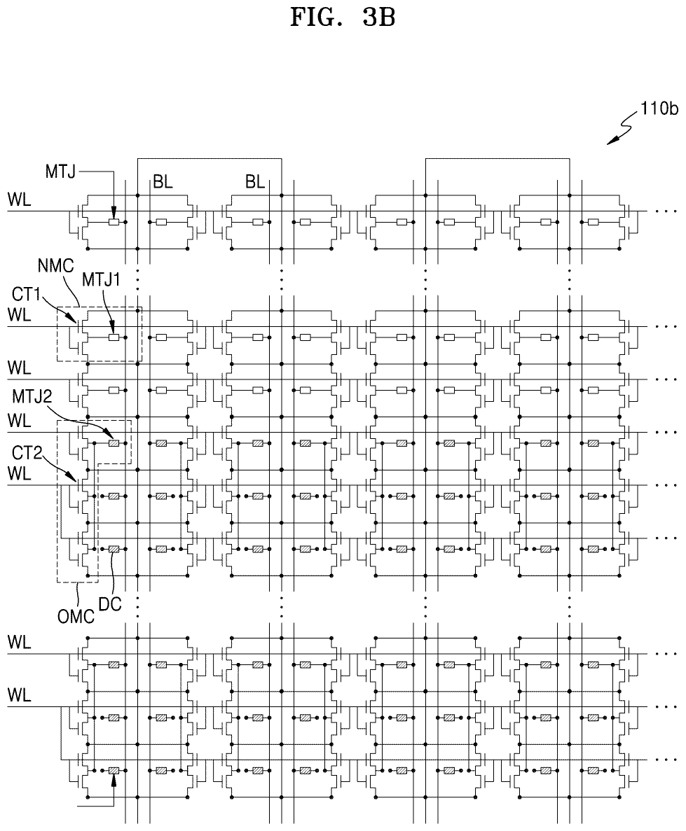

The normal memory cell NMC and the OTP memory cell OMC may each include a variable resistance element and a cell transistor. Hereinafter, the variable resistance element and the cell transistor included in the normal memory cell NMC are referred to as a first variable resistance element (e.g., a first variable resistance element MTJ1 of FIG. 3A) and a first cell transistor (e.g., a first cell transistor CT1 of FIG. 3A), respectively, and the variable resistance element and the cell transistor included in the OTP memory cell OMC are referred to as a second variable resistance element (e.g., a second variable resistance element MTJ2 of FIG. 3A) and a second cell transistor (e.g., a second cell transistor CT2 of FIG. 3A), respectively. A row of the normal memory cells NMC may be connected to a corresponding word line WL1, and a row of the OTP memory cells OMC may be connected to a corresponding word line WLn.

The OTP memory cells OMC may be programed once. Once programmed, data programmed thereto is unchangeable and is retained even after power supply is removed. The OTP memory cells OMC may store security-critical data. For example, the OTP memory cell OMC may store digital security tokens, smart cards, keys, passwords, boot codes, production settings, manufacturing settings, setting values of the memory device 10, trim values, etc. The second variable resistance element of the OTP memory cell OMC may destroy insulation of a tunnel barrier layer (e.g., a barrier layer TBL of FIG. 2A) by applying a breakdown voltage BV through one programming operation, thereby obtaining an irreversible resistance state.

The OTP memory cell OMC stores security-critical data such as the setting value of the memory device 10, and thus, when reading data stored in the OTP memory cell OMC, it is necessary or desired to reduce minimize data errors and secure a wide read margin. As will be described later with reference to the drawings, the memory device 10 may secure a relatively wide read margin for the OTP memory cell OMC, and thus, when reading data stored in the OTP memory cell OMC, errors may be reduced and data reliability may be improved. Also, because the cell array 110 and peripheral circuits may be utilized as-is, the memory device 10 may have a simple structure and low cost. Also, since a separate non-volatile storage device or memory chip for storing security-critical data may be omitted, a system including the memory device 10 may have a simple structure and low cost.

According to an example embodiment, the structure of the OTP memory cell OMC may be identical to that of the normal memory cell NMC. For example, the normal memory cell NMC may include one first cell transistor and one first variable resistance element. The OTP memory cell OMC may include one second cell transistor and one second variable resistance element. However, the inventive concepts are not limited thereto. The structure of the OTP memory cell OMC may be different from that of the normal memory cell NMC. For example, the normal memory cell NMC may include one first cell transistor and one first variable resistance element and the OTP memory cell OMC may include three second cell transistors and one second variable resistance element.

The cell array 110 may include a plurality of reference cells NRC and ORC. The cell array 110 may include a normal reference cell NRC and an OTP reference cells ORC. The normal reference cell NRC may refer to a reference cell corresponding to the normal memory cell NMC. The normal reference cell NRC may be connected to the word line WL corresponding to the normal memory cell NMC. For example, the normal memory cell NMC and the normal reference cell NRC may share the word line WL1. The normal reference cell NRC may be used to determine a value stored in the normal memory cell NMC. When one of the plurality of word lines WLs is activated by the row decoder 120 and an activated word line WL1 corresponds to the normal memory cell NMC, not only the normal memory cell NMC connected to the activated word line WL1, but also the normal reference cell NRC connected to the activated word line WL1 may be selected. For example, the normal memory cell NMC and the normal reference cell NRC may be selected by the activated word line WL1.

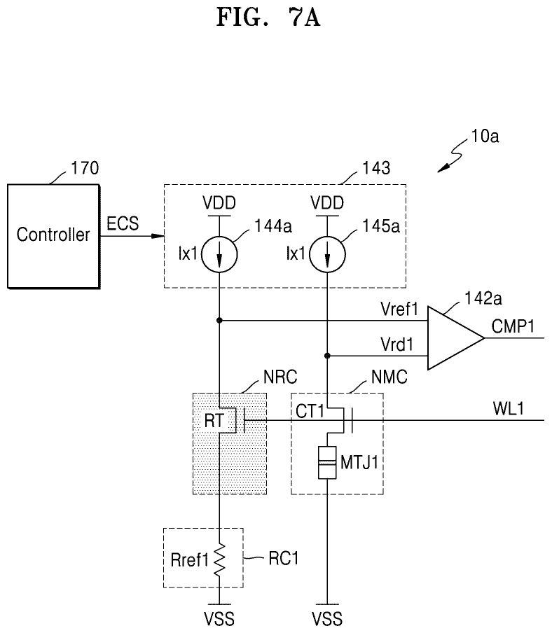

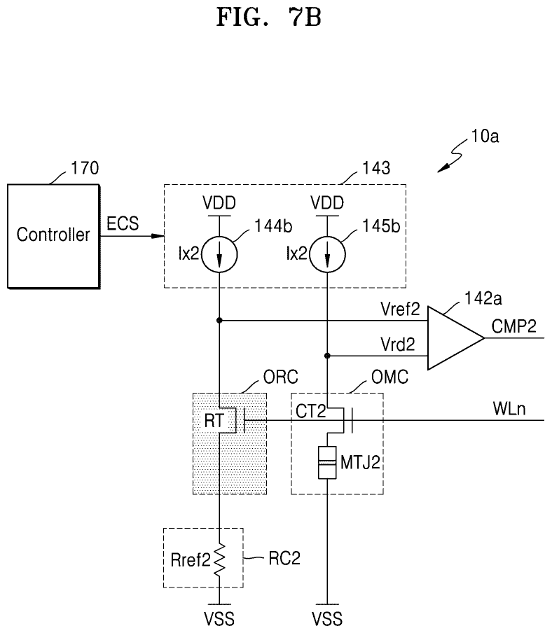

When determining a value stored in the normal memory cell NMC, the normal reference cell NRC corresponding to the normal memory cell NMC may be used. For example, the normal reference cell NRC selected by the same word line as the normal memory cell NMC may be used to read data stored in the normal memory cell NMC. The normal reference cell NRC may have a first reference resistance value. According to an example embodiment, the normal reference cell NRC may include a resistance element such as a variable resistance element, and the fact that the normal reference cell NRC has the first reference resistance value may mean that the resistance value of a resistance element included in the normal reference cell NRC corresponds to the first reference resistance value. However, the inventive concepts are not limited thereto. According to an example embodiment, the normal reference cell NRC may be a shorted cell in which a resistance element such as a variable resistance element is omitted. When the normal reference cell NRC is a shorted cell, the normal reference cell NRC may include a resistance circuit (e.g., a first resistance circuit RC1 of FIG. 7A) connected to the normal reference cell NRC outside the cell array 110. The fact that the normal reference cell NRC has the first reference resistance value may mean that the resistance value of a resistance circuit connected to the normal reference cell NRC corresponds to the first reference resistance value.

Data stored in the normal memory cell NMC may be read based on the first reference resistance value. For example, to determine data stored in the normal memory cell NMC, the resistance value of the first variable resistance element of the normal memory cell NMC may be compared with the first reference resistance value of the normal reference cell NRC.

The OTP reference cell ORC may refer to a reference cell corresponding to the OTP memory cell OMC. The OTP reference cell ORC may be connected to the word line WLn corresponding to the OTP memory cell OMC. For example, the OTP memory cell OMC and the OTP reference cell ORC may share the word line WLn. The OTP reference cell ORC may be used to determine a value stored in the OTP memory cell OMC. When one of the plurality of word lines WLs is activated by the row decoder 120 and an activated word line W Ln corresponds to the OTP memory cell OMC, not only the OTP memory cell OMC connected to the activated word line WLn, but also the OTP reference cell ORC connected to the activated word line WLn may be selected. For example, the OTP memory cell OMC and the OTP reference cell ORC may be selected by the activated word line WLn.

When determining a value stored in the OTP memory cell OMC, the OTP reference cell ORC corresponding to the OTP memory cell OMC may be used. For example, the OTP reference cell ORC selected by the same word line as the OTP memory cell OMC may be used to read data stored in the OTP memory cell OMC. The OTP reference cell ORC may have a second reference resistance value. According to an example embodiment, the OTP reference cell ORC may include a resistance element such as a variable resistance element, and the fact that the OTP reference cell ORC has the second reference resistance value may mean that the resistance value of a resistance element included in the OTP reference cell ORC corresponds to the second reference resistance value. However, the inventive concepts are not limited thereto. According to an example embodiment, the OTP reference cell ORC may be a shorted cell in which a resistance element such as a variable resistance element is omitted. When the OTP reference cell ORC is a shorted cell, the OTP reference cell ORC may include a resistance circuit (e.g., a second resistance circuit RC2 of FIG. 7B) connected to the OTP reference cell ORC outside the cell array 110. The fact that the OTP reference cell ORC has the second reference resistance value may mean that the resistance value of a resistance circuit connected to the OTP reference cell ORC corresponds to the second reference resistance value.

Data stored in the OTP memory cell OMC may be read based on the second reference resistance value. For example, to determine data stored in the OTP memory cell OMC, the resistance value of the second variable resistance element of the OTP memory cell OMC may be compared with the second reference resistance value of the OTP reference cell ORC.

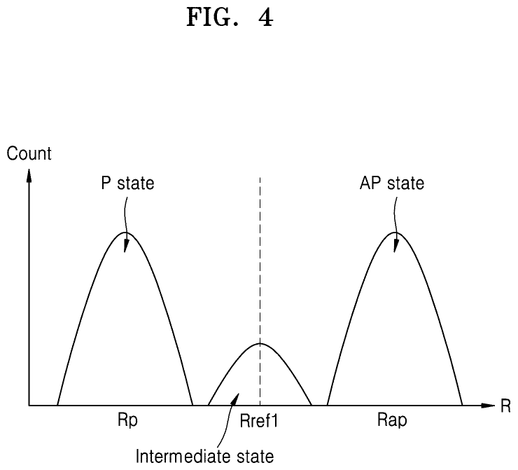

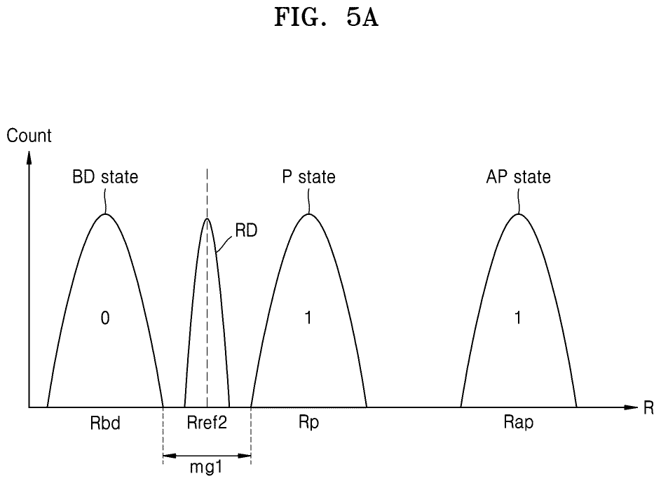

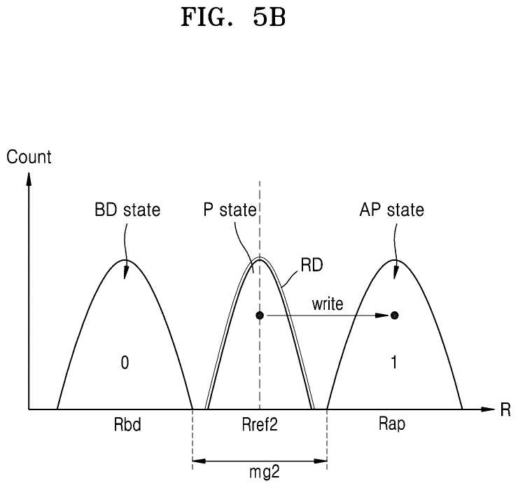

According to an example embodiment, the first reference resistance value of the normal reference cell NRC may be different from the second reference resistance value of the OTP reference cell ORC. The first reference resistance value may be a resistance value to distinguish between a parallel state (e.g., a parallel state P of FIG. 4) and an anti-parallel state (e.g., an anti-parallel state AP of FIG. 4) of the normal memory cell NMC. The second reference resistance value may be a resistance value to distinguish between a breakdown state (e.g., a breakdown state BD of FIG. 5B) and an anti-parallel state (e.g., the anti-parallel state AP of FIG. 5B) of the OTP memory cell OMC. In other words, the first reference resistance value may be a resistance value to distinguish between the parallel state P and the anti-parallel state AP of a variable resistance element of a memory cell, and the second reference resistance value may be a resistance value to distinguish between the breakdown state BD and the anti-parallel state AP of the variable resistance element. For example, the first reference resistance value may be the median value of the resistance value of the variable resistance element in the parallel state P and the resistance value of the variable resistance element in the anti-parallel state AP, and the second reference resistance value may be the median value of the resistance value of the variable resistance element in the breakdown state BD and the resistance value of the variable resistance element in the anti-parallel state AP. However, the inventive concepts are not limited thereto. States of the normal memory cell NMC and the OTP memory cell OMC will be described later with reference to FIGS. 4 to 5B.

The row decoder 120 may activate at least one of the plurality of word lines WLs based on a row address ROW provided by the address decoder 150, and memory cells and reference cells connected to an activated word line may be selected. For example, the row decoder 120 may activate one of the word lines WLs connected to the normal memory cells NMC in response to the row address ROW and may also activate one of the word lines WLs connected to the OTP memory cells OMC.

The column decoder 130 may be connected to the cell array 110 through the plurality of bit lines BLs. The column decoder 130 may select a memory cell based on a column address COL provided by the address decoder 150. According to an example embodiment, the column decoder 130 may select a memory cell according to the column address COL and select a reference cell corresponding to a selected memory cell. For example, the column decoder 130 may select the normal memory cell NMC based on the column address COL and select the normal reference cell NRC corresponding to the normal memory cell NMC. The column decoder 130 may select the OTP memory cell OMC based on the column address COL and select the OTP reference cell ORC corresponding to the OTP memory cell OMC.

The read circuit 140 may be connected to the column decoder 130 through output bit lines BLOs. For example, the output bit lines BLOs include a first output bit line and a second output bit line, and the read circuit 140 may determine a value stored in a memory cell based on signals received through the first output bit line and the second output bit line and generate a data signal D_OUT including a determined value. For example, the first output bit line may be connected to a memory cell, and the second output bit line may be connected to a reference cell, but the inventive concepts are not limited thereto.

The read circuit 140 may provide a pre-set or desired electrical signal to each of a memory cell and a reference cell, and determine a value stored in the memory cell by detecting signals passing through the memory cell and the reference cell. During a read operation of the normal memory cell NMC, the read circuit 140 may provide a pre-set or desired electrical signal to each of the normal memory cell NMC and the normal reference cell NRC and determine a value stored in the normal memory cell NMC by detecting signals passing through the normal memory cell NMC and the normal reference cell NRC through the output bit lines BLOs. The read circuit 140 may read data stored in the normal memory cell NMC based on the first reference resistance value during a read operation of the normal memory cell NMC. The read circuit 140 may determine a value stored in the normal memory cell NMC by using a signal generated based on the first reference resistance value, through the normal reference cell NRC and output bit lines connected to the normal reference cell NRC.

During a read operation of the OTP memory cell OMC, the read circuit 140 may provide a pre-set or desired electrical signal to each of the OTP memory cell OMC and the OTP reference cell ORC and determine a value stored in the OTP memory cell OMC by detecting signals passing through the OTP memory cell OMC and the OTP reference cell ORC through the output bit lines BLOs. The read circuit 140 may read data stored in the OTP memory cell OMC based on the second reference resistance value during a read operation of the OTP memory cell OMC. The read circuit 140 may determine a value stored in the OTP memory cell OMC by using a signal generated based on the second reference resistance value, through the OTP reference cell ORC and output bit lines connected to the OTP reference cell ORC.

According to an example embodiment, during a read operation of the OTP memory cell OMC, the read circuit 140 may write the OTP memory cell OMC in an anti-parallel state and then read data stored in the OTP memory cell OMC based on the second reference resistance value. When the read operation of the OTP memory cell OMC, the read circuit 140 may make the OTP memory cell OMC in an anti-parallel state. For example, by writing the current to the OTP memory cell OMC, the OTP memory cell OMC may be written in an anti-parallel state. For example, the second reference resistance value may be a resistance value to distinguish between a breakdown state and an anti-parallel state of the OTP memory cell OMC. During a read operation of an OTP memory cell OMC, it is necessary or desired to distinguish between a breakdown state and a non-breakdown state, and the non-breakdown state may include a parallel state and an anti-parallel state. A resistance value corresponding to the breakdown state may be lower than a resistance value corresponding to the parallel state, and a resistance value corresponding to the parallel state may be lower than a resistance value corresponding to the anti-parallel state. When a resistance value between the breakdown state and the parallel state is used to distinguish between the breakdown state and the non-breakdown state, the read margin may be relatively narrow.

To relatively widen the read margin, the memory device 10 may use a resistance value between the breakdown state and the anti-parallel state as the second reference resistance value. When a resistance value between the breakdown state and the anti-parallel state is used as the second reference resistance value, data in the parallel state may be incorrectly read out in the breakdown state, and thus, during the read operation of the OTP memory cells OMC, the OTP memory cells OMC may be made in the anti-parallel state. The OTP memory cells OMC in the breakdown state are not written in the anti-parallel state, and only the OTP memory cells OMC in the parallel state may be written in the anti-parallel state. In other words, because the OTP memory cells OMC may be in the breakdown state or the anti-parallel state, the read circuit 140 may perform a read operation by using the second reference resistance value between the breakdown state and the anti-parallel state. For example, the read circuit 140 may perform a read operation by using the second reference resistance value in the parallel state.

The read circuit 140 may include a read driver 141 and a sense amplifier 142. However, although not shown in FIG. 1, the read circuit 140 may further include other components in addition to the read driver 141 and the sense amplifier 142, as needed. The read circuit 140 may provide an electrical signal of a pre-set or desired magnitude to each of a memory cell and a reference cell, and determine a value stored in the memory cell by detecting currents passing through the memory cell and the reference cell. For example, the read driver 141 may provide an electrical signal of a pre-set or desired magnitude to each of the memory cell and the reference cell. The sense amplifier 142 may detect currents passing through the memory cell and the reference cell.

According to an example embodiment, the read circuit 140 may provide a current of a pre-set or desired magnitude to each of the memory cell and the reference cell. An electrical signal may include a current, and the read driver 141 may provide a current of a pre-set or desired magnitude to each of the memory cell and the reference cell. According to an example embodiment, the read driver 141 may include a current generator that provides currents to the memory cell and the reference cell. The sense amplifier 142 may be a voltage sense amplifier. The sense amplifier 142 may determine a value stored in the memory cell by detecting voltages applied to the memory cell and the reference cell.

According to an example embodiment, the read circuit 140 may provide a voltage of a pre-set or desired magnitude to each of the memory cell and the reference cell. An electrical signal may include a voltage, and the read driver 141 may provide a voltage of a pre-set or desired magnitude to each of the memory cell and the reference cell. According to an example embodiment, the read driver 141 may include a voltage generator that provides voltages to the memory cell and the reference cell. The sense amplifier 142 may be a current sense amplifier. The sense amplifier 142 may determine a value stored in the memory cell by detecting currents passing through the memory cell and the reference cell. Although not shown in FIG. 1, the memory device 10 may further include a write circuit for writing data to memory cells.

The read circuit 140 may provide different electrical signals depending on whether a read operation is a read operation of the normal memory cell NMC or a read operation of the OTP memory cell OMC. According to an example embodiment, the read driver 141 may provide a first electrical signal to the normal memory cell NMC and a second electrical signal to the OTP memory cell OMC. The magnitude of the second electrical signal may be greater than the magnitude of the first electrical signal. For example, based on a control signal ECS generated by the controller 170, the read circuit 140 may provide the first electrical signal to the normal memory cell NMC and provide the second electrical signal to the OTP memory cell OMC. According to some example embodiments, the read driver 141 may provide the first electrical signal to the normal reference cell NRC and provide the second electrical signal to the OTP reference cell ORC. However, the inventive concepts are not limited thereto. An electrical signal of a magnitude different from that of the first electrical signal may be provided to the normal reference cell NRC, and an electrical signal of a magnitude different from that of the second electrical signal may be provided to the OTP reference cell ORC.

During a read operation of the normal memory cell NMC, the sense amplifier 142 may determine a value stored in the normal memory cell NMC by detecting the difference between a first input signal applied by the normal memory cell NMC and a first reference signal applied by the normal reference cell NRC, based on the first electrical signal. During a read operation of the OTP memory cell OMC, the sense amplifier 142 may determine a value stored in the OTP memory cell OMC by detecting the difference between a second input signal applied by the OTP memory cell OMC and a second reference signal applied by the OTP reference cell ORC, based on the second electrical signal. The memory device 10 may provide the OTP memory cell OMC with an electrical signal of a magnitude greater than that of an electrical signal applied to the normal memory cell NMC, thereby reducing the power consumption of the memory device 10 and improving the read margin of the OTP memory cell OMC.

According to an example embodiment, a period in which the read operation of the OTP memory cell OMC is performed may be longer than a period in which the read operation of the normal memory cell NMC is performed. When the period in which the read operation of the OTP memory cell OMC is performed is relatively long, the sense amplifier 142 may detect the difference between the second input signal applied by the OTP memory cell OMC and the second reference signal applied by the OTP reference cell ORC more easily and read margin may be improved.

The address decoder 150 may generate a row address ROW and a column address COL based on an address ADDR. The data buffer 160 may receive the data signal D_OUT from the read circuit 140 and store data corresponding to the data signal D_OUT. The data buffer 160 may provide stored data to an input/output circuit.

Although not shown in FIG. 1, the memory device 10 may further include an input/output circuit. The input/output circuit may provide a memory interface. For example, the input/output circuit may receive a command CM D and an address ADDR from the outside and receive or output data DATA from or to the outside. The input/output circuit may provide the address ADDR to the address decoder 150 and may provide the command CM D and the address ADDR to the controller 170. The input/output circuit may provide received data DATA to the data buffer 160 and output the data signal D_OUT provided by the data buffer 160 to the outside as the data DATA.

The controller 170 may generally control the memory device 10. The controller 170 may control components of the memory device 10 based on the command CM D. For example, the controller 170 may identify an instruction for a write operation or a read operation based on the command CM D and control the components of the memory device 10 to perform a write operation or a read operation.

According to an example embodiment, the controller 170 may control the components of the memory device 10 based on the address ADDR. Because the normal memory cell NMC and the OTP memory cell OMC may be connected to different word lines, a read operation of the normal memory cell NMC and a read operation of the OTP memory cell OMC may be distinguished from each other based on the address ADDR. For example, the controller 170 may identify a read operation of the OTP memory cell OMC based on the row address ROW and the command CMD and control the components of the memory device 10 to perform the read operation of the OTP memory cell OMC. However, the inventive concepts are not limited thereto, and the read operation of the OTP memory cell OMC may be identified based on the column address COL.

The controller 170 may generate the control signal ECS to control the read circuit 140. During a read operation of the OTP memory cell OMC, the read circuit 140 may write the OTP memory cell OMC in the anti-parallel state based on the control signal ECS and then read data stored in the OTP memory cell OMC based on the second reference resistance value.

According to an example embodiment, based on the control signal ECS, the read circuit 140 may provide the first electrical signal to the normal memory cell NMC during a read operation of the normal memory cell NMC and may provide the second electrical signal to the OTP memory cell OMC during a read operation of the OTP memory cell OMC.

According to an example embodiment, the controller 170 may control the row decoder 120 and the read circuit 140, such that the period in which the read operation of the OTP memory cell OMC is performed is longer than the period in which the read operation of the normal memory cell NMC is performed. For example, the row decoder 120 may activate a word line connected to a memory cell based on a control signal RCS. During a read operation of the normal memory cell NMC, the row decoder 120 may activate a word line connected to the normal memory cell NMC during a first period based on the control signal RCS. During a read operation of the OTP memory cell OMC, the row decoder 120 may activate a word line connected to the OTP memory cell OMC during a second period, which is longer than the first period, based on the control signal RCS.

For example, the memory device 10 further includes a sensing switching element connecting the cell array 110 and the sense amplifier 142, and the controller 170 may control the sensing switching element. The controller 170 may increase a period in which the sensing switching element is activated during a read operation of the OTP memory cell OMC to be greater than a period in which the sensing switching element is activated during a read operation of the normal memory cell NMC. The row decoder 120 may activate a word line connected to the OTP memory cell OMC during the second period, which is longer than the first period, based on the control signal RCS. The controller 170 may control a word line and a sensing switching element, such that the period in which the read operation of the OTP memory cell OMC is performed is longer than the period in which the read operation of the normal memory cell NMC is performed.

FIG. 2A is a diagram showing an example memory cell according to an example embodiment. A memory cell M C of FIG. 2A may be applied to the normal memory cell NMC and the OTP memory cell OMC of FIG. 1. Descriptions identical to those already given above will be omitted.

Referring to FIG. 2A, the memory cell M C may include the variable resistance element MTJ and the cell transistor CTj connected in series between the source line SLj and a bit line BLj. When the memory cell M C is the normal memory cell NMC, the variable resistance element MTJ may be a first variable resistance element, and the cell transistor CT may be a first cell transistor. When the memory cell M C is the OTP memory cell OMC, the variable resistance element MTJ may be a second variable resistance element, and the cell transistor CT may be a second cell transistor. Although FIG. 2A shows that the memory cell M C includes one variable resistance element MTJ and one cell transistor CT, it is merely an example, and the numbers of variable resistance elements MTJ and cell transistors CT included in the memory cell M C may vary.

According to some example embodiments, as shown in FIG. 2A, the variable resistance element MTJ and the cell transistor CTj may be in series in the order stated between the source line SLj and the bit line BLj. According to some other example embodiments, unlike as shown in FIG. 2A, the cell transistor CT and the variable resistance element MTJ may be connected in series in the order stated between the source line SLj and the bit line BLj.

The variable resistance element MTJ may include a free layer FL, a pinned layer PL, and a barrier layer TBL between the free layer FL and the pinned layer PL. As indicated by arrows in FIG. 2A, the magnetization direction of the pinned layer PL may be fixed, whereas the free layer FL may have a magnetization direction identical or opposite to the magnetization direction of the pinned layer PL. When the pinned layer PL and the free layer FL have the same magnetization directions, it may be said that the variable resistance element MTJ is in the parallel state (e.g., the parallel state P of FIG. 4). On the other hand, when the pinned layer PL and the free layer FL have magnetization directions opposite to each other, it may be said that the variable resistance element MTJ is in the anti-parallel state (e.g., the anti-parallel state AP of FIG. 4). According to some example embodiments, the variable resistance element MTJ may further include an anti-ferromagnetic layer, such that the pinned layer PL has a fixed magnetization direction.

When the memory cell MC is the normal memory cell NMC of FIG. 1, the variable resistance element MTJ may have a relatively low resistance value (e.g., Rp of FIG. 4) in the parallel state P and may have a relatively high resistance value Rap in the anti-parallel state AP. In this specification, it is assumed that the memory cell M C stores “0” when the variable resistance element MTJ in the parallel state P has a low resistance value Rp and the memory cell M C stores “1” when the variable resistance element MTJ in the anti-parallel state AP has the high resistance value Rap.

The cell transistor CTj may have a gate connected to a word line WLi and a source and a drain connected to the bit line BLj and the variable resistance element MTJ. The cell transistor CTj may electrically connect or block between the variable resistance element MTJ and the bit line BLj depending on a signal applied to the word line Wli. For example, to write “0” to the memory cell MC in a write operation, a cell transistor CTj may be turned on, and a current from the source line SLj to the bit line BLj may pass through the variable resistor element MTJ and cell transistor CT. Also, to write “1” to the memory cell M C, the cell transistor CTj may be turned on, and a current from the bit line BLj to the source line SLj may pass through the cell transistor CT and the variable resistance element MTJ. In a read operation, the cell transistor CTj may be turned on, and a current from the source line SLj to the bit line BLj or a current from the bit line BLj to the source line SLj (e.g., a read current) may pass through the cell transistor CTj and variable resistance element MTJ.

When the memory cell M C is the OTP memory cell OMC of FIG. 1, the variable resistance element MTJ may have a relatively low resistance value (e.g., Rp of FIG. 5A) in the parallel state P and may have a relatively high resistance value (e.g., Rap of FIG. 5A) in the anti-parallel state AP. Meanwhile, the variable resistance element MTJ may have a relatively lower resistance value (e.g., Rbd of FIG. 5A) in a breakdown state (e.g., the breakdown state BD of FIG. 5A). The cell transistor CT may apply a breakdown current, which is higher than a typical write current applied to the variable resistance element MTJ, to the OTP memory cell OMC. The breakdown current may damage or destroy the barrier layer TBL of the variable resistance element MTJ. The much lower resistance value Rbd in the breakdown state BD is lower than the low resistance value Rp in the parallel state P and the high resistance value Rap in the anti-parallel state AP. Once the variable resistance element MTJ is in the breakdown state BD, it is impossible to switch the variable resistance element MTJ to another state.

Hereinafter, it is assumed that, in the OTP memory cell OMC, the memory cell M C stores “0” when the variable resistance element MTJ in the breakdown state BD has the much lower resistance value Rbd and the memory cell MC stores “1” when the variable resistance element MTJ in the parallel state P has the low resistance value Rp and the variable resistance element MTJ in the anti-parallel state AP has the high resistance value Rap.

In the OTP memory cell OMC, to write “0” to the memory cell M C in a write operation, a cell transistor CTj may be turned on, and a breakdown current from the source line SLj to the bit line BLj may pass through the variable resistor element MTJ and cell transistor CT.

FIG. 2B is a diagram showing an example reference cell according to an example embodiment. A reference cell RC of FIG. 2B may be applied to the normal reference cell NRC and the OTP reference cell ORC of FIG. 1. Descriptions identical to those already given above will be omitted. Compared to the memory cell MC of FIG. 2A, the variable resistance element MTJ may be omitted in the reference cell RC, and the reference cell RC may be referred to as a shorted cell. Hereinafter, descriptions will be given with reference to FIG. 2A together.

The reference cell RC may include a reference cell transistor RT. The reference cell transistor RT may have a gate connected to the word line Wli and a source and a drain connected to a bit line BLk and a source line SLk. The reference cell transistor RT may electrically connect or block between the source line SLk and the bit line BLj depending on a signal applied to the word line Wli.

A memory device (e.g., the memory device 10 of FIG. 1) may include a resistance circuit (e.g., the first resistance circuit RC1 of FIG. 7A and the second resistance circuit RC2 of FIG. 7B) outside a cell array (e.g., the cell array 110 of FIG. 1), and to determine a value stored in the memory cell MC, the resistance value of the variable resistance element MTJ may be compared with the resistance value of the resistance circuit based on the reference cell RC, which is a shorted cell. Hereinafter, it is assumed that the reference cell RC is a shorted cell like the reference cell RC of FIG. 2B. However, the inventive concepts are not limited thereto, and it will be understood that a reference cell including the variable resistance element MTJ is also applicable.

FIG. 3A is a diagram illustrating a cell array according to an example embodiment. Referring to FIG. 3A, a cell array 110a may include the normal memory cell NMC and the OTP memory cell OMC. Although omitted in FIG. 3A, a normal reference cell and an OTP reference cell may be included in the cell array 110a. The cell array 110a of FIG. 3A may correspond to the cell array 110 of FIG. 1. Descriptions identical to those already given above will be omitted.

The normal memory cell NMC may include the first variable resistance element MTJ1 and the first cell transistor CT1. A gate of the first cell transistor CT1 is connected to the word line WL, a drain of the first cell transistor CT1 is connected to one end of the first variable resistance element MTJ1, and a source of the first cell transistor CT1 is connected to a source line SL. The other end of the first variable resistance element MTJ1 is connected to the bit line BL.

The OTP memory cell OMC may include the second variable resistance element MTJ2 and the second cell transistor CT2. A gate of the second cell transistor CT2 is connected to the word line WL, a drain of the second cell transistor CT2 is connected to one end of the second variable resistance element MTJ2, and a source of the second cell transistor CT2 is connected to the source line SL. The other end of the second variable resistance element MTJ2 is connected to the bit line BL.

According to some example embodiments, the OTP memory cell OMC may have the same structure as the normal memory cell NMC. For example, an 1T-1R structure in which one normal memory cell NMC is connected to one first cell transistor CT1 may constitute one unit normal memory cell NMC in the cell array 110a, and an 1T-1R structure in which one OTP memory cell OMC is connected to one second cell transistor CT2 may constitute one unit OTP memory cell OMC in the cell array 110a. However, the inventive concepts are not limited thereto, and the normal memory cell NMC and the OTP memory cell OMC may have various structures such as a 2T-2R structure in which two memory cells NMC and OMC adjacent to two cell transistors CT are commonly connected to the two cell transistors.

FIG. 3B is a diagram illustrating a cell array according to an example embodiment. Referring to FIG. 3B, a cell array 110b may include the normal memory cell NMC and the OTP memory cell OMC. Compared to FIG. 3A, the structures of the normal memory cell NMC and OTP memory cell OMC may be different from those in FIG. 3A. The cell array 110b of FIG. 3B may correspond to the cell array 110 of FIG. 1. Descriptions identical to those already given above will be omitted.

The OTP memory cell OMC may have a structure different from that of the normal memory cell NMC. According to an example embodiment, the number of first cell transistors CT1 included in the OTP memory cell OMC may be greater than the number of second cell transistors CT2 included in the normal memory cell NMC. The normal memory cell NMC may include one first variable resistance element MTJ1 and two first cell transistors CT1. A 2T-1R structure in which one normal memory cell NMC is connected to two first cell transistors CT1 may constitute one unit normal memory cell NMC in the cell array 110b.

The OTP memory cell OMC may include one second variable resistance element MTJ2 and six second cell transistors CT2. The second cell transistors CT2 may be connected in parallel to the second variable resistance element MTJ2. The second cell transistors CT2 may apply a higher breakdown current to the OTP memory cell OMC. A 6T-1R structure in which one OTP memory cell OMC is connected to six second cell transistors CT2 may constitute one unit OTP memory cell OMC in the cell array 110b. However, it is merely an example, and the inventive concepts are not limited thereto.

The cell array 110b may include dummy cells DC, wherein the dummy cells DC may not be connected to the second cell transistors CT2 and word lines corresponding to the dummy cells DC and may not be connected to the bit line BL and the source line SL corresponding to the dummy cells DC.

FIG. 4 is a graph showing the distribution and change of resistance values of a variable resistance element included in a normal memory cell, according to an example embodiment.

Referring to FIG. 4, a graph shows the distribution of resistance values R that a variable resistance element included in a normal memory cell (e.g., the normal memory cell NMC of FIG. 1) of a memory device (e.g., the memory device 10 of FIG. 1) may have is shown. In the graph of FIG. 4, the horizontal axis represents resistance values R of a variable resistance elements included in the normal memory cell NMC, and the vertical axis represents the number (counts) of variable resistance elements having the corresponding resistance values.

When the resistance value R of a variable resistance element corresponds to the relatively low resistance value Rp, the variable resistance element may be in the parallel state P. When the variable resistance element is in the parallel state P, the normal memory cell NMC including the variable resistance element may store 0.

When the resistance value R of a variable resistance element corresponds to the relatively high resistance value Rap, the variable resistance element may be in the anti-parallel state AP. When the variable resistance element is in the anti-parallel state AP, the normal memory cell NMC including the variable resistance element may store 1.

When the resistance value R of the variable resistance element corresponds to an approximately median value of the resistance value of the variable resistance element in the parallel state P and the resistance value of the variable resistance element in the anti-parallel state AP, the variable resistance element may be in an intermediate state. Due to its physical characteristics, a variable resistance element is unable to maintain the intermediate state for a long time. In other words, when a variable resistance element is in the intermediate state, the state of the variable resistance element may be switched to the parallel state P or the anti-parallel state AP within a short period of time.

According to an example embodiment, a first reference resistance value Rref1 may be a resistance value between the low resistance value Rp and the high resistance value Rap. For example, an average value of the resistance value Rp in the parallel state P and the resistance value Rap in the anti-parallel state AP may be set as a first reference resistance value Rref1. At this time, the first reference resistance value Rref1 may be set as the resistance value of a normal reference cell (e.g., the normal reference cell NRC of FIG. 1). When the normal reference cell NRC is a shorted cell, a resistance circuit connected to the normal reference cell NRC (e.g., the first resistance circuit RC1 of FIG. 7A) may be set to the first reference resistance value Rref1. However, the inventive concepts are not limited thereto, and, when the normal reference cell NRC includes a resistance element, the first reference resistance value Rref1 may be set as the resistance value of the resistance element included in the normal reference cell NRC. During a read operation of the normal memory cell NMC, the memory device 10 may determine the value of data stored in the normal memory cell NMC based on the first reference resistance value Rref1.

FIG. 5A is a graph showing the distribution and change of resistance values of a variable resistance element included in an OTP memory cell, according to an example embodiment.

Referring to FIG. 5A, a graph showing the distribution of resistance values R that a variable resistance element included in an OTP memory cell (e.g., the OTP memory cell OMC of FIG. 1) of a memory device (e.g., the memory device 10 of FIG. 1) may have is shown. In the graph of FIG. 5A, the horizontal axis represents resistance values R of a variable resistance elements included in the OTP memory cell OMC, and the vertical axis represents the number (counts) of variable resistance elements having the corresponding resistance values.

When the resistance value R of a variable resistance element corresponds to the relatively low resistance value Rp, the variable resistance element may be in the parallel state P. When the resistance value R of a variable resistance element corresponds to the relatively high resistance value Rap, the variable resistance element may be in the anti-parallel state AP. When the variable resistance element is in the parallel state P or the anti-parallel state AP, the OTP memory cell OMC including the variable resistance element may store 1.

When the resistance value R of a variable resistance element corresponds to the much lower resistance value Rbd, the variable resistance element may be in the breakdown state BD. When the variable resistance element is in the breakdown state BD, the OTP memory cell OMC including the variable resistance element may store 0. The resistance value Rbd in the breakdown state BD may be the lowest.

According to an example embodiment, a second reference resistance value Rref2 may be a resistance value between the low resistance value Rp and the much lower resistance value Rbd. For example, an average value of the resistance value Rp in the parallel state P and the resistance value Rbd in the breakdown state BD may be set as a second reference resistance value Rref2. However, the inventive concepts are not limited thereto. The OTP memory cell may have a read margin mg1, and a read operation of the OTP memory cell OMC may be performed by using the second reference resistance value Rref2 between the breakdown state BD and the parallel state P.

At this time, the second reference resistance value Rref2 may be set as the resistance value of an OTP reference cell (e.g., the OTP reference cell ORC of FIG. 1). FIG. 5A shows a graph showing a distribution RD of the resistance values R of the OTP reference cell ORC. When the OTP reference cell ORC is a shorted cell, a resistance circuit connected to the OTP reference cell ORC (e.g., the second resistance circuit RC2 of FIG. 7b) may be set to the second reference resistance value Rref2. However, the inventive concepts are not limited thereto, and, when the OTP reference cell ORC includes a resistance element, the second reference resistance value Rref2 may be set as the resistance value of the resistance element included in the OTP reference cell ORC. During a read operation of the OTP memory cell OMC, the memory device 10 may determine the value of data stored in the OTP memory cell OMC based on the second reference resistance value Rref2.

FIG. 5B is a graph showing the distribution and change of resistance values of a variable resistance element included in an OTP memory cell, according to an example embodiment. Compared to FIG. 5A, the second reference resistance value Rref2 may be different in FIGS. 5A and 5B. Descriptions identical to those already given above will be omitted.

According to an example embodiment, a second reference resistance value Rref2 may be a resistance value between the high resistance value Rap and the much lower resistance value Rbd. For example, an average value of the resistance value Rap in the anti-parallel state AP and the resistance value Rbd in the breakdown state BD may be set as the second reference resistance value Rref2. However, the second reference resistance value Rref2 is not necessarily an average value. For example, the resistance value Rp in the parallel state P may be set as the second reference resistance value Rref2.

According to an example embodiment, during a read operation of the OTP memory cell OMC, the memory device 10 may write to the OTP memory cell OMC in the anti-parallel state AP and then read data stored in the OTP memory cell OMC based on the second reference resistance value Rref2. At the time of a read operation of the OTP memory cell OMC, the memory device 10 may perform a write operation to write the OTP memory cell OMC in the anti-parallel state AP and then immediately perform a read operation of the OTP memory cell OMC.

During a read operation of an OTP memory cell OMC, it is necessary or desired to distinguish between the breakdown state B D and a non-breakdown state, and the non-breakdown state may include the parallel state P and the anti-parallel state AP. When the resistance value R between the breakdown state BD and the anti-parallel state AP is used as the second reference resistance value Rref2, data in the parallel state P may be incorrectly read in the breakdown state BD, and thus, during a read operation of the OTP memory cells OMC, the memory device 10 may write the OTP memory cells OMC in the anti-parallel state AP. The OTP memory cells OMC in the breakdown state BD are not written in the anti-parallel state AP, and only the OTP memory cells OMC in the parallel state P may be written in the anti-parallel state AP. A read operation of the OTP memory cell OMC may be performed by using the second reference resistance value Rref2 between the breakdown state BD and the anti-parallel state AP.

The second reference resistance value Rref2 may be set as the resistance value of the OTP reference cell ORC. FIG. 5B shows a graph showing a distribution RD of the resistance values R of the OTP reference cell ORC. The second reference resistance value Rref2 may be a resistance value between the resistance value Rbd in the breakdown state B D and the resistance value Rap in the anti-parallel state AP. The OTP memory cell OMC may have a read margin mg2. By using a resistance value between the breakdown state BD and the anti-parallel state AP as the second reference resistance value Rref2, the read margin mg2 may be widened and the reliability of the memory device 10 may be improved.

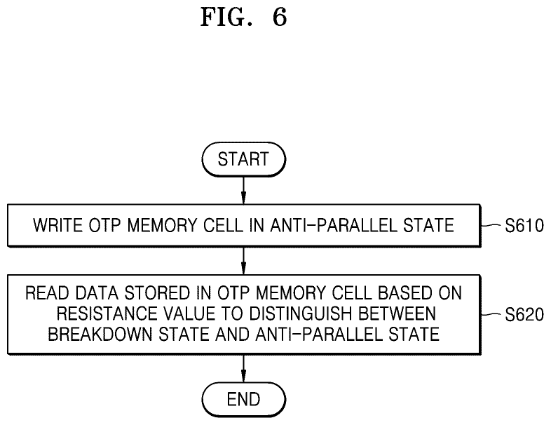

FIG. 6 is a flowchart of a method of operating a memory device, according to an example embodiment. FIG. 6 illustrates a method of operating the memory device 10 of FIG. 1. For example, FIG. 6 shows a method of operating the read circuit 140. Hereinafter, FIGS. 1 and 6 will be referred to together. Descriptions identical to those already given above will be omitted.

FIG. 6 shows a method of reading the OTP memory cell OMC. The memory device 10 may read data stored in the OTP memory cell OMC based on the second reference resistance value. The memory device 10 may determine a value stored in the OTP memory cell OMC by using a signal generated based on the second reference resistance value, through the OTP reference cell ORC and output to bit lines connected to the OTP reference cell ORC.

In operation S610, the memory device 10 may write the OTP memory cell OMC in the anti-parallel state during a read operation of the OTP memory cell OMC. For example, the second reference resistance value may be a resistance value to distinguish between a breakdown state and an anti-parallel state of the OTP memory cell OMC. To relatively widen the read margin, the memory device 10 may use a resistance value between the breakdown state and the anti-parallel state as the second reference resistance value.

When a resistance value between the breakdown state and the anti-parallel state is used as the second reference resistance value, the memory device 10 may write the OTP memory cells OMC in the anti-parallel state. As the OTP memory cells OMC become the anti-parallel state, the memory device 10 may perform a read operation by using the second reference resistance value between the breakdown state and the anti-parallel state.

In operation S620, the memory device 10 may read data stored in the OTP memory cell OMC based on the resistance value to distinguish between the breakdown state and the anti-parallel state. The second reference resistance value may be a resistance value between a resistance value in the breakdown state and a resistance value in the anti-parallel state.

The memory device 10 may provide electrical signals of a pre-set or desired magnitude to the OTP memory cell OMC and the OTP reference cell ORC and may determine a value stored on the OTP memory cell OMC by detecting signals passing through the OTP memory cell OMC and the OTP reference cell ORC. For example, the read driver 141 may provide electrical signals of a pre-set or desired magnitude to the OTP memory cell OMC and the OTP reference cell ORC. The sense amplifier 142 may detect signals passing through the OTP memory cell OMC and the OTP reference cell ORC.

The memory device 10 may provide electrical signals of a magnitude greater than the magnitude of electrical signals provided to the normal memory cell NMC and the normal reference cell NRC to the OTP memory cell OMC and the OTP reference cell ORC. For example, the memory device 10 provides first electrical signals to the normal memory cell NMC and the normal reference cell NRC and provides second electrical signals of a magnitude greater than the magnitude of the first electrical signals to the OTP memory cell OMC and the OTP reference cell ORC.

According to an example embodiment, the memory device 10 may provide a pre-set or desired amount of current to each of the OTP memory cell OMC and the OTP reference cell ORC. The memory device 10 may determine a value stored in a memory cell by detecting currents flowing in the OTP memory cell OMC and the OTP reference cell ORC.

According to an example embodiment, the memory device 10 may provide a voltage of a pre-set or desired magnitude to each of the OTP memory cell OMC and the OTP reference cell ORC. The memory device 10 may determine a value stored in a memory cell by detecting voltages applied to the OTP memory cell OMC and the OTP reference cell ORC.

FIG. 7A is a block diagram showing a memory device according to an example embodiment. In detail, FIG. 7A is an equivalent circuit diagram schematically showing the structure of a memory device 10a during a read operation of the normal memory cell NMC, and the memory device 10a of FIG. 7A may correspond to the memory device 10 of FIG. 1. Descriptions identical to those already given above will be omitted.

Referring to FIG. 7A, the memory device 10a may include the controller 170, a current generator 143, a sense amplifier 142a, the normal reference cell NRC, the normal memory cell NMC, and the first resistance circuit RC1. The current generator 143 and the sense amplifier 142a may be included in the read circuit 140 of FIG. 1. FIG. 7A shows a read operation of a normal memory cell NMC. The current generator 143 and the sense amplifier 142a may be connected to the normal memory cell NMC and the normal reference cell NRC. FIG. 7A is described below under the assumption that the sense amplifier 142a is a voltage sense amplifier. Also, although FIG. 7A is described under the assumption that the normal reference cell NRC is a shorted cell, the description of FIG. 7A may also be applied to the case where the normal reference cell NRC includes a variable resistance element.

The normal reference cell NRC and the normal memory cell NMC may be included in a cell array of the memory device 10a and may be connected to the same word line WL1. FIG. 7A is described below under the assumption that the normal reference cell NRC and the normal memory cell NMC are connected to the word line WL1. The normal memory cell NMC may include the first cell transistor CT1 and the first variable resistance element MTJ1. The normal reference cell NRC may be a shorted cell and may include the reference cell transistor RT.

The memory device 10a may include the first resistance circuit RC1 connected to the normal reference cell NRC outside the cell array. The normal reference cell NRC may have a first reference resistance value Rref1. The fact that the normal reference cell NRC has the first reference resistance value Rref1 may mean that the first resistance circuit RC1 connected to the normal reference cell NRC has the first reference resistance value Rref1. For example, the first reference resistance value Rref1 may be a resistance value to distinguish between the parallel state and the anti-parallel state of the normal memory cell NMC. Data stored in the normal memory cell NMC may be read based on the first reference resistance value Rref1.

The controller 170 may control the current generator 143 through the control signal ECS. The controller 170 may generate the control signal ECS for controlling the current generator 143 depending on whether the read operation is a read operation of the normal memory cell NMC or a read operation of the OTP memory cell OMC. The controller 170 may control the current generator 143 to generate a first current Ix1 based on the control signal ECS.

During a read operation of the normal memory cell NMC, the current generator 143 may provide a pre-set or desired electrical signal to each of the normal memory cell NMC and the normal reference cell NRC. The current generator 143 may provide the first current Ix1 to each of the normal memory cell NMC and the normal reference cell NRC. For example, the current generator 143 may include a first current source 144a and a second current source 145a. The first current source 144a and the second current source 145a may each generate the first current Ix1 of the same magnitude. As shown in FIG. 7A, the first current Ix1 generated by the first current source 144a may flow from a positive supply voltage VDD to a negative supply voltage VSS through the normal reference cell NRC and the first resistance circuit RC1, and the first current Ix1 generated by the second current source 145a may flow from the positive supply voltage VDD to the negative supply voltage VSS through the normal memory cell NMC.

During a read operation of the normal memory cell NMC, the sense amplifier 142a may determine a value stored in the normal memory cell NMC by detecting the difference between a first input signal Vrd1 applied by the normal memory cell NMC and a first reference signal Vref1 applied by the normal reference cell NRC, based on the first electrical signal. The sense amplifier 142a may detect the difference between the first input signal Vrd1, which is the voltage of the normal memory cell NMC, and the first reference signal Vref1, which is the voltage of the normal reference cell NRC, based on the first current Ix1. The sense amplifier 142a may generate a comparison signal CMP1 by comparing the first reference signal Vref1, which is generated by the normal reference cell NRC and the first resistance circuit RC1, with the first input signal Vrd1, which is generated by the normal memory cell NMC. The comparison signal CMP1 may represent a value stored in the normal memory cell NMC. The memory device 10a may generate the data signal D_OUT from the comparison signal CMP1.

FIG. 7B is a block diagram showing a memory device according to an example embodiment. In detail, FIG. 7B is an equivalent circuit diagram schematically showing the structure of a memory device 10a during a read operation of the OTP memory cell OMC, and the memory device 10a of FIG. 7B may correspond to the memory device 10 of FIG. 1. Descriptions identical to those already given above with reference to FIG. 7A will be omitted. Hereinafter, descriptions will be given with reference to FIG. 7A together.

FIG. 7B shows a read operation of the OTP memory cell OMC. The current generator 143 and the sense amplifier 142a may be connected to the OTP memory cell OMC and the OTP reference cell ORC. The OTP reference cell ORC and the OTP memory cell OMC may be included in a cell array of the memory device 10a and may be connected to the same word line WLn. FIG. 7B is described below under the assumption that the OTP reference cell ORC and the OTP memory cell OMC are connected to the word line WLn. The OTP memory cell OMC may include the second cell transistor CT2 and the second variable resistance element MTJ2. The OTP reference cell ORC may be a shorted cell and may include the reference cell transistor RT.

The memory device 10a may include the second resistance circuit RC2 connected to the OTP reference cell ORC outside the cell array. The OTP reference cell ORC may have the second reference resistance value Rref2. The fact that the OTP reference cell ORC has the second reference resistance value Rref2 may mean that the second resistance circuit RC2 connected to the OTP reference cell ORC has the second reference resistance value Rref2. For example, the second reference resistance value Rref2 may be a resistance value to distinguish between a breakdown state and an anti-parallel state of the OTP memory cell OMC. However, the inventive concepts are not limited thereto, and the second reference resistance value Rref2 may be a resistance value to distinguish between the breakdown state and the parallel state of the OTP memory cell OMC. Data stored in the OTP memory cell OMC may be read based on the second reference resistance value Rref2.

The controller 170 may control the current generator 143 through the control signal ECS. The controller 170 may control the current generator 143 to generate a second current Ix2 based on the control signal ECS. The controller 170 may control the current generator 143 to provide the first current Ix1 to the normal memory cell NMC and the normal reference cell NRC during a read operation of the normal memory cell NMC and provide the second current Ix2 to the OTP memory cell OMC and the OTP reference cell ORC during a read operation of the OTP memory cell OMC.

During a read operation of the OTP memory cell OMC, the current generator 143 may provide the second current Ix2 to each of the OTP memory cell OMC and the OTP reference cell ORC. According to an example embodiment, the magnitude of the second current Ix2 may be greater than the magnitude of the first current Ix1. However, the inventive concepts are not limited thereto, and the magnitude of the second current Ix2 may be identical to that of the first current lx1. For example, the current generator 143 may include a first current source 144b and a second current source 145b, and the first current source 144b and the second current source 145b may each generate the second current Ix2 of the same magnitude.

As shown in FIG. 7B, the second current Ix2 may flow from the positive supply voltage VDD to the negative supply voltage VSS through the OTP reference cell ORC and the second resistance circuit RC2. Also, the second current Ix2 may flow from the positive supply voltage VDD to the negative supply voltage VSS through the OTP memory cell OMC.

During a read operation of the OTP memory cell OMC, the sense amplifier 142a may determine a value stored in the OTP memory cell OMC by detecting the difference between a second input signal Vrd2 applied by the OTP memory cell OMC and a second reference signal Vref2 applied by the OTP reference cell ORC, based on the second current Ix2. The sense amplifier 142a may generate a comparison signal CMP2 by comparing the second reference signal Vref2, which is a voltage by the OTP reference cell ORC and the second resistance circuit RC2, with the second input signal Vrd2, which is a voltage by the OTP memory cell OMC. The comparison signal CMP2 may represent a value stored in the OTP memory cell OMC. The memory device 10a may generate the data signal D_OUT from the comparison signal CMP2.

Because the magnitude of the second current Ix2 is greater than the magnitude of the first current Ix1, the magnitude of the second input signal Vrd2 may be greater than the magnitude of the first input signal Vrd1, and the magnitude of the second reference signal Vref2 may be greater than the magnitude of the first reference signal Vref1. Also, because the magnitude of the second current Ix2 is greater than the magnitude of the first current Ix1, the difference between the second input signal Vrd2 and the second reference signal Vref2 may be greater than difference between the first input signal Vrd1 and the first reference signal Vref1. The memory device 10a may provide the OTP memory cell OMC with a current of a magnitude greater than that of a current applied to the normal memory cell NMC, thereby reducing the power consumption of the memory device 10a and improving the read margin of the OTP memory cell OMC.

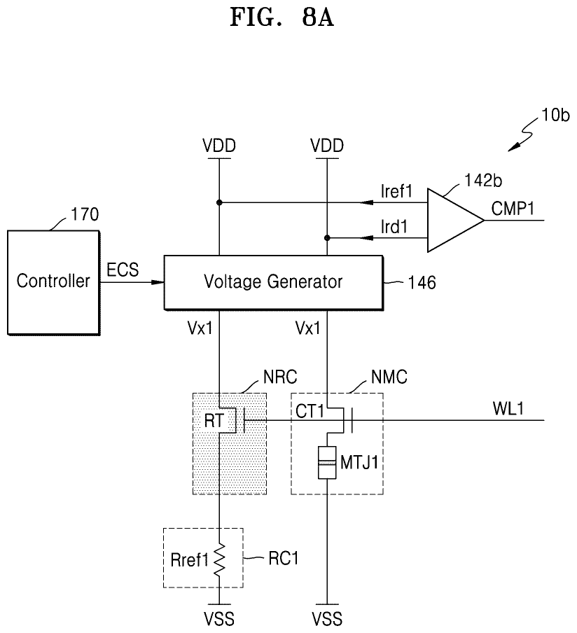

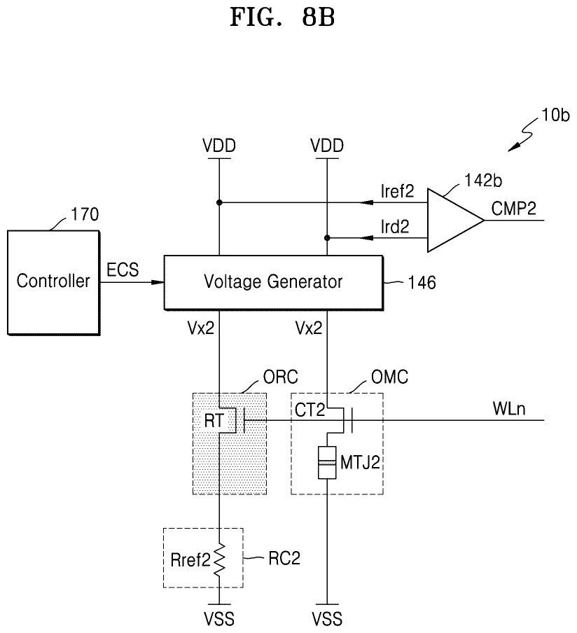

FIG. 8A is a block diagram showing a memory device according to an example embodiment. In detail, FIG. 8A is an equivalent circuit diagram schematically showing the structure of a memory device 10b during a read operation of the normal memory cell NMC, and the memory device 10b of FIG. 8A may correspond to the memory device 10 of FIG. 1. Compared with FIG. 7A, FIG. 8A is described under the assumption that a sense amplifier 142b is a current sense amplifier. Descriptions identical to those already given above will be omitted.

Referring to FIG. 8A, the memory device 10b may include the controller 170, a voltage generator 146, the sense amplifier 142b, the normal reference cell NRC, the normal memory cell NMC, and the first resistance circuit RC1. The voltage generator 146 and the sense amplifier 142b may be included in the read circuit 140 of FIG. 1. FIG. 8A shows a read operation of a normal memory cell NMC. The voltage generator 146 and the sense amplifier 142b may be connected to the normal memory cell NMC and the normal reference cell NRC.

The controller 170 may control the voltage generator 146 through the control signal ECS. The controller 170 may generate the control signal ECS for controlling the voltage generator 146 depending on whether the read operation is a read operation of the normal memory cell NMC or a read operation of the OTP memory cell OMC. The controller 170 may control the voltage generator 146 to generate a first voltage Vx1 based on the control signal ECS.

During a read operation of the normal memory cell NMC, the voltage generator 146 may provide the first voltage Vx1 to each of the normal memory cell NMC and the normal reference cell NRC. As shown in FIG. 8A, the first voltage Vx1 may be provided to the normal reference cell NRC, and the sense amplifier 142b may detect a first reference signal Iref1, which is a current passing through the normal reference cell NRC and the first resistance circuit RC1, based on the first voltage Vx1. The first voltage Vx1 may be provided to the normal memory cell NMC, and the sense amplifier 142b may detect a first input signal Ird1, which is a current passing through the normal memory cell NMC, based on the first voltage Vx1.

During a read operation of the normal memory cell NMC, the sense amplifier 142b may determine a value stored in the normal memory cell NMC by detecting the difference between the first input signal Ird1 applied by the normal memory cell NMC and the first reference signal Iref1 applied by the normal reference cell NRC, based on the first voltage Vx1. The sense amplifier 142b may detect the difference between the first input signal Ird1 and the first reference signal Iref1 based on the first voltage Vx1. The sense amplifier 142b may generate a comparison signal CMP1 by comparing the first reference signal Iref1 by the normal reference cell NRC and the first resistance circuit RC1 with the first input signal Ird1 by the normal memory cell NMC.

FIG. 8B is a block diagram showing a memory device according to an example embodiment. In detail, FIG. 8B is an equivalent circuit diagram schematically showing the structure of a memory device 10b during a read operation of the OTP memory cell OMC, and the memory device 10b of FIG. 8B may correspond to the memory device 10 of FIG. 1. Compared with FIG. 7B, FIG. 8B is described under the assumption that a sense amplifier 142b is a current sense amplifier. Descriptions identical to those already given above with reference to FIG. 8A will be omitted. Hereinafter, descriptions will be given with reference to FIG. 8A together.

FIG. 8B shows a read operation of the OTP memory cell OMC. The voltage generator 146 and the sense amplifier 142b may be connected to the OTP memory cell OMC and the OTP reference cell ORC.

The controller 170 may control the voltage generator 146 through the control signal ECS. The controller 170 may control the voltage generator 146 to generate a second voltage Vx2 based on the control signal ECS. The controller 170 may control the voltage generator 146 to provide the first voltage Vx1 to the normal memory cell NMC and the normal reference cell NRC during a read operation of the normal memory cell NMC and provide the second voltage Vx2 to the OTP memory cell OMC and the OTP reference cell ORC during a read operation of the OTP memory cell OMC.

During a read operation of the OTP memory cell OMC, the voltage generator 146 may provide the second voltage Vx2 to each of the OTP memory cell OMC and the OTP reference cell ORC. According to an example embodiment, the magnitude of the second voltage Vx2 may be greater than the magnitude of the first voltage Vx1. However, the inventive concepts are not limited thereto, and the magnitude of the second voltage Vx2 may be identical to that of the first voltage Vx1.

As shown in FIG. 8B, the second voltage Vx2 may be provided to the OTP reference cell ORC, and the sense amplifier 142b may detect a second reference signal Iref2, which is a current passing through the OTP reference cell ORC and the second resistance circuit RC2, based on the second voltage Vx2. The second voltage Vx2 may be provided to the OTP memory cell OMC, and the sense amplifier 142b may detect a second input signal Ird2, which is a current passing through the OTP memory cell OMC, based on the second voltage Vx2.

During a read operation of the OTP memory cell OMC, the sense amplifier 142b may determine a value stored in the OTP memory cell OMC by detecting the difference between the second input signal Ird2 applied by the OTP memory cell OMC and the second reference signal Iref2 applied by the OTP reference cell ORC, based on the second voltage Vx2. The sense amplifier 142b may generate a comparison signal CMP2 by comparing the second reference signal Iref2 by the OTP reference cell ORC and the second resistance circuit RC2 with the second input signal Ird2 by the OTP memory cell OMC.

Because the magnitude of the second voltage Vx2 is greater than the magnitude of the first voltage Vx1, the magnitude of the second input signal Ird2 may be greater than the magnitude of the first input signal Ird1, and the magnitude of the second reference signal Iref2 may be greater than the magnitude of the first reference signal Iref1. Also, because the magnitude of the second voltage Vx2 is greater than the magnitude of the first voltage Vx1, the difference between the second input signal Ird2 and the second reference signal Iref2 may be greater than difference between the first input signal Ird1 and the first reference signal Iref1. The memory device 10b may provide the OTP memory cell OMC with a voltage of a magnitude greater than that of a current applied to the normal memory cell NMC, thereby reducing the power consumption of the memory device 10a and improving the read margin of the OTP memory cell OMC.

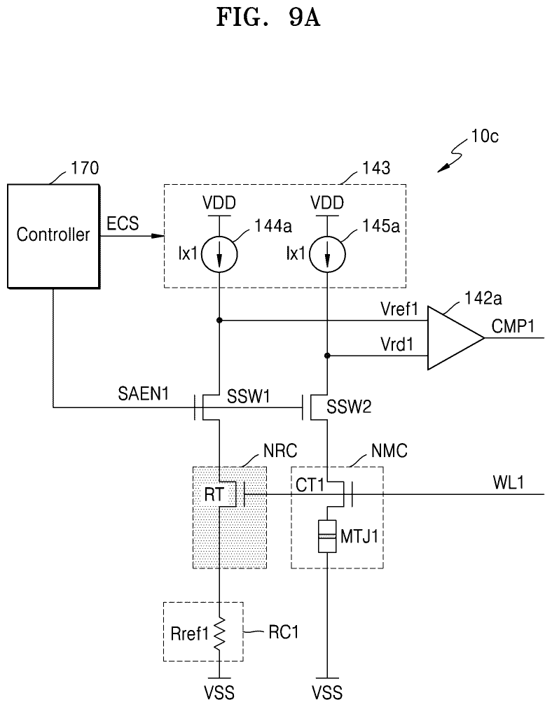

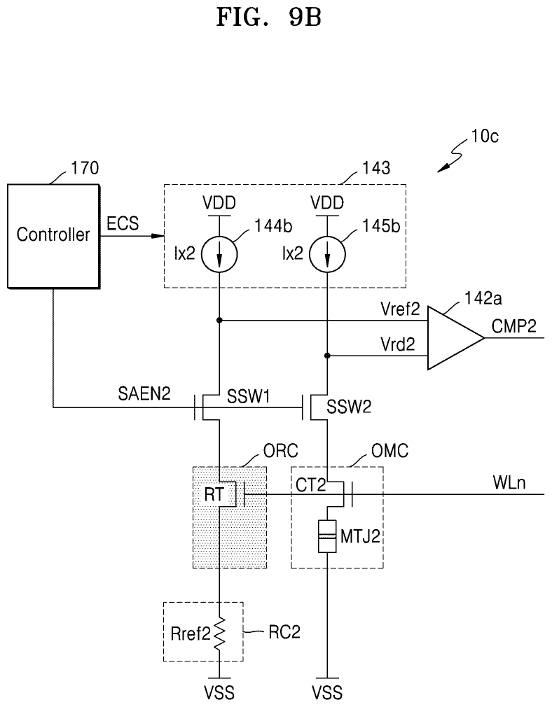

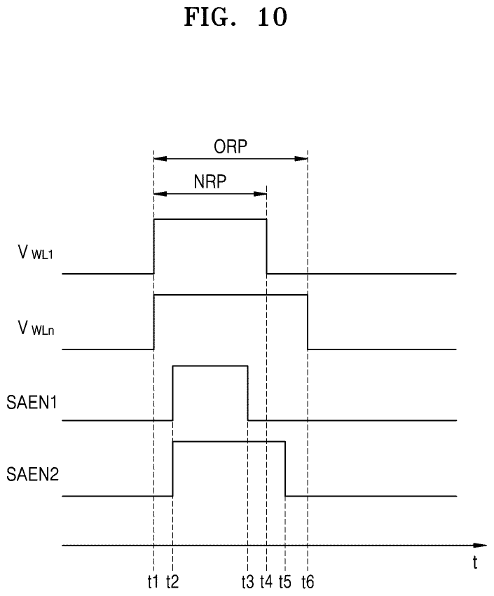

FIG. 9A is a diagram showing the structure of a memory device during a read operation of the normal memory cell NMC, according to an example embodiment, FIG. 9B is the structure of a memory device during a read operation of the OTP memory cell OMC, according to an example embodiment, and FIG. 10 is a timing diagram showing an example of the operation of a memory device, according to an example embodiment. In FIGS. 9A and 9B, the memory device 10c includes the voltage sense amplifier 142a, but descriptions of FIGS. 9A through 10 may also be applied to a memory device including a current sense amplifier. Comparing FIG. 9A with FIG. 7A, a memory device 10c of FIG. 9A may further include a first sensing switching element SSW1 and a second sensing switching element SSW2. Comparing FIG. 9B with FIG. 7B, the memory device 10c of FIG. 9B may further include the first sensing switching element SSW1 and the second sensing switching element SSW2. Descriptions identical to those already given above will be omitted. Hereinafter, FIGS. 9A to 10 will be referred to together.

Referring to FIGS. 9A and 10, the memory device 10c may further include the first sensing switching element SSW1 and the second sensing switching element SSW2. During a read operation of the normal memory cell NMC, the first sensing switching element SSW1 may be connected between the sense amplifier 142a and the normal reference cell NRC. The second sensing switching element SSW2 may be connected between the sense amplifier 142a and the normal memory cell NMC. The first sensing switching element SSW1 and the second sensing switching element SSW2 may be turned off or turned on according to a first sensing control signal SAEN1. During a read operation of the normal memory cell NMC, the controller 170 may generate the first sensing control signal SAEN1 for controlling the operation of the first sensing switching element SSW1 connected to the normal reference cell NRC and the second sensing switching element SSW2 connected to the normal memory cell NMC. A word line voltage VwL1 represents the voltage of the word line WL1.

Referring to FIGS. 9B and 10, the memory device 10c may further include the first sensing switching element SSW1 and the second sensing switching element SSW2. During a read operation of the OTP memory cell OMC, the first sensing switching element SSW1 may be connected between the sense amplifier 142a and the OTP reference cell ORC. The second sensing switching element SSW2 may be connected between the sense amplifier 142a and the OTP memory cell OMC. The first sensing switching element SSW1 and the second sensing switching element SSW2 may be turned off or turned on according to a second sensing control signal SAEN2. During a read operation of the OTP memory cell OMC, the controller 170 may generate the second sensing control signal SAEN2 for controlling the operation of the first sensing switching element SSW1 connected to the OTP reference cell ORC and the second sensing switching element SSW2 connected to the OTP memory cell OMC. A word line voltage V_{WLn} represents the voltage of the word line WLn.

An OTP read period ORP in which a read operation of the OTP memory cell OMC is performed may be longer than a normal read period NRP in which a read operation of the normal memory cell NMC is performed. For example, a read period may be set based on a period in which a word line is activated and a period in which a sensing switching element is activated.

According to an example embodiment, a period in which the word line WLn connected to the OTP memory cell OMC is activated during a read operation of the OTP memory cell OMC may be longer than a period in which the word line WL1 connected to the normal memory cell NMC is activated during a read operation of the normal memory cell NMC. The controller 170 may control the word line WLn connected to the OTP memory cell OMC to be activated for a relatively long period of time during a read operation of the OTP memory cell OMC. For example, the controller 170 may generate a control signal (e.g., the control signal RCS of FIG. 1) for controlling the word line WLn connected to the OTP memory cell OMC to be activated for a relatively long period of time during a read operation of the OTP memory cell OMC, and a row decoder (e.g., the row decoder 120 of FIG. 1) may activate word lines WL1 and WLn based on the control signal RCS.

The controller 170 may control such that the word line voltage VwL1 is applied to the word line WL1 during a read operation of the normal memory cell NMC, and the word line WL1 may be activated from a first time point t1 to a fourth time point t4 according to the word line voltage VwL1. The controller 170 may control such that the word line voltage V_{WLn} is applied to the word line WLn during a read operation of the OTP memory cell OMC, and the word line WLn may be activated from the first time point t1 to a sixth time point t6 according to the word line voltage V_{WLn}. The time period between the first time point t1 and the sixth time point t6 may be longer than the time period between the first time point t1 and the fourth time point t4.

According to an example embodiment, the controller 170 may control such that a period in which the first sensing switching element SSW1 and the second sensing switching element SSW2 are activated during a read operation of the OTP memory cell OMC is longer than a period in which the first sensing switching element SSW1 and the second sensing switching element SSW2 are activated during a read operation of the normal memory cell NMC. During a read operation of the normal memory cell NMC, the controller 170 may provide the first sensing control signal SAEN1 to the first sensing switching element SSW1 and the second sensing switching element SSW2, and the first sensing switching element SSW1 and the second sensing switching element SSW2 may be activated from a second time point t2 to a third time point t3.

During a read operation of the OTP memory cell OMC, the controller 170 may provide the second sensing control signal SAEN2 to the first sensing switching element SSW1 and the second sensing switching element SSW2, and the first sensing switching element SSW1 and the second sensing switching element SSW2 may be activated from the second time point t2 to a fifth time point t5. The time period between the second time point t2 and the fifth time point t5 may be longer than the time period between the second time point t2 and the third time point t3.

When the OTP read period ORP is relatively long, the sense amplifier 142a may detect the difference between the second input signal Vrd2 applied by the OTP memory cell OMC and the second reference signal Vref2 applied by the OTP reference cell ORC more easily and read margin may be improved.

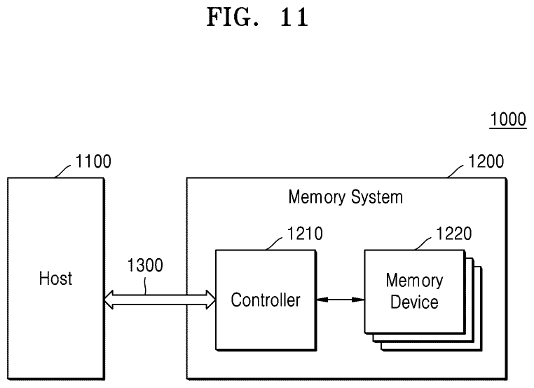

FIG. 11 is a block diagram showing a memory system 1000 including a memory device according to an example embodiment.

Referring to FIG. 11, a memory system 1200 may communicate with the host 1100 and may include a memory controller 1210 and a memory device 1220. The memory device 10 described above with reference to FIGS. 1 to 10 may be applied to the memory device 1220.

The interface 1300 through which the memory system 1200 and the host 1100 communicate with each other may use electrical signals and/or optical signals via a wire or wirelessly, and may be implemented by, but is not limited to, a serial advanced technology attachment (SATA) interface, an SATA express (SATAe) interface, a serial attached small computer system interface (SCSI) (SAS), a peripheral component interconnect express (PCIe) interface, a non-volatile memory express (NV M e) interface, an advanced host controller interface (AHCI), a communication thereof.

According to some example embodiments, the memory system 1200 may communicate with the host 1100 by being removably coupled to host 1100. As a resistive memory, the memory device 1220 may be a non-volatile memory, and the memory system 1200 may also be referred to as a storage system. For example, as a non-limiting example, the memory system 1200 may be implemented by a solid-state drive or solid-state disk (SSD), an embedded SSD (eSSD), a multimedia card (MMC), an embedded multimedia card (eMMC), etc.

The memory controller 1210 may control the memory device 1220 in response to a request received from the host 1100 through the interface 1300. For example, the memory controller 1210 may write data received along with a write request to the memory device 1220 in response to the write request and provide data stored in the memory device 1220 to the host 1100 in response to a read request.

The memory system 1200 may include at least one memory device 1220. The memory device 1220 may be implemented like the memory device 10 described above with reference to FIGS. 1 to 10.

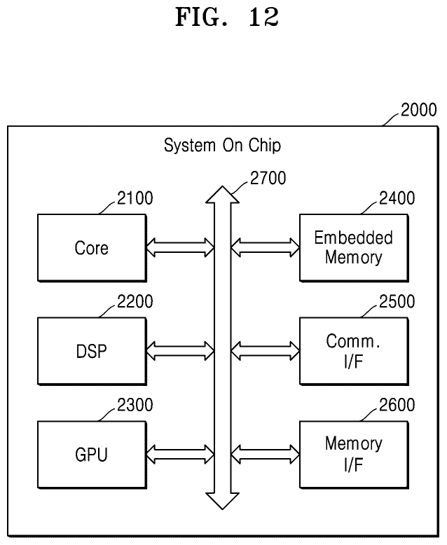

FIG. 12 is a block diagram showing a system-on-chip (SoC) including a memory device, according to an example embodiment.

Referring to FIG. 12, a SoC 2000 may include a core 2100, a digital signal processor (DSP) 2200, a graphic processing unit (GPU) 2300, an embedded memory 2400, a communication interface 2500, and a memory interface 2600. The components of the SoC 2000 may communicate with one another through a bus 2700.

The SoC 2000 may refer to an integrated circuit that integrates components of a computing system or other electronic system. For example, as an example of the SoC 2000, an application processor (AP) may include a processor and parts for other functions.

The core 2100 may process instructions and control operations of the components included in the SoC 2000. For example, the core 2100 may process a series of instructions, thereby driving an operating system and executing applications on the operating system. The DSP 2200 may generate useful data by processing digital signals, e.g., digital signals provided from the communication interface 2500. The GPU 2300 may generate data for images output through a display device from image data provided from the embedded memory 2400 or the memory interface 2600 or encode image data. The communication interface 2500 may provide an interface for a communication network or one-to-one communication. The memory interface 2600 may provide an interface for an external memory of the SoC 2000, e.g., a dynamic random access memory (DRAM), a flash memory, etc.

The embedded memory 2400 may store data needed for operations of the core 2100, the DSP 2200, and the GPU 2300. The embedded memory 2400 may include the memory device 10 described above with reference to FIGS. 1 to 10.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (A SIC), etc.

While the inventive concepts have been particularly shown and described with reference to some example embodiments thereof, it will be understood that various changes in form and details may be made therein without departing from the spirit and scope of the following claims.

What is claimed is:

1. A memory device comprising:
a cell array comprising a normal memory cell and a one-time programmable (OTP) memory cell, the normal memory cell configured to be programmable a plurality of number of times, an OTP memory cell configured to be programmable once;
a controller configured to control such that a first electrical signal is applied to the normal memory cell during a read operation of the normal memory cell and a second electrical signal is applied to the OTP memory cell during a read operation of the OTP memory cell;
a read driver configured to provide the first electrical signal to the normal memory cell and the second electrical signal to the OTP memory cell based on a control signal from the controller; and
a sense amplifier configured to detect a first input signal applied from the normal memory cell based on the first electrical signal and detect a second input signal applied from the OTP memory cell based on the second electrical signal,
wherein a magnitude of the second electrical signal is greater than a magnitude of the first electrical signal.

2. The memory device of claim 1, wherein
the cell array further comprises a normal reference cell corresponding to the normal memory cell and an OTP reference cell corresponding to the OTP memory cell, and
the sense amplifier is further configured to
detect a difference between a first reference signal applied from the normal reference cell and the first input signal based on the first electrical signal during the read operation of the normal memory cell, and
detect a difference between the second input signal and a second reference signal applied from the OTP reference cell based on the second electrical signal during the read operation of the OTP memory cell.

3. The memory device of claim 2, wherein the difference between the second input signal and the second reference signal is greater than the difference between the first input signal and the first reference signal.

4. The memory device of claim 2, wherein
a magnitude of the second input signal is greater than a magnitude of the first input signal, and
a magnitude of the second reference signal is greater than a magnitude of the first reference signal.

5. The memory device of claim 2, wherein
the first electrical signal comprises a first current and the second electrical signal comprises a second current,
the read driver is further configured to
provide the first current to the normal memory cell and the normal reference cell during the read operation of the normal memory cell, and
provide the second current to the OTP memory cell and the OTP reference cell during the read operation of the OTP memory cell, and
a magnitude of the second current is greater than a magnitude of the first current.

6. The memory device of claim 2, wherein
the first electrical signal comprises a first voltage and the second electrical signal comprises a second voltage,
the read driver is further configured to
provide the first voltage to the normal memory cell and the normal reference cell during the read operation of the normal memory cell, and
provide the second voltage to the OTP memory cell and the OTP reference cell during the read operation of the OTP memory cell, and
a magnitude of the second voltage is greater than a magnitude of the first voltage.

7. The memory device of claim 1, wherein the controller is further configured to:
activate a word line connected to the normal memory cell during a first period during the read operation of the normal memory cell; and
activate a word line connected to the OTP memory cell during a second period, which is longer than the first period, during the read operation of the OTP memory cell.

8. The memory device of claim 7, wherein
the memory device further comprises a sensing switching element connecting between the cell array and the sense amplifier, and
the controller is further configured to increase a period in which the sensing switching element is activated during the read operation of the OTP memory cell to be greater than a period in which the sensing switching element is activated during the read operation of the normal memory cell.

9. The memory device of claim 1, wherein
the memory device is further configured to receive a row address to select a word line connected to the cell array, and
the controller is further configured to generate the control signal based on the row address.

10. The memory device of claim 1, wherein
the cell array further comprises a normal reference cell corresponding to the normal memory cell and an OTP reference cell corresponding to the OTP memory cell, and
a first reference resistance value of the normal reference cell is different from a second reference resistance value of the OTP reference cell.

11. The memory device of claim 10, wherein
the first reference resistance value is a median value of a resistance value of the normal memory cell in a parallel state and a resistance value of the normal memory cell in an anti-parallel state, and
the second reference resistance value is a median value of a resistance value of the OTP memory cell in a breakdown state and a resistance value of the OTP memory cell in an anti-parallel state.

12. The memory device of claim 11, wherein, during the read operation of the OTP memory cell, the controller is further configured to control such that the OTP memory cell to be written in the anti-parallel state before the second electrical signal is provided to the OTP memory cell.

13. The memory device of claim 1, wherein
each of the normal memory cell and the OTP memory cell comprises at least one cell transistor, and
a number of cell transistors included in the OTP memory cell is greater than a number of cell transistors included in the normal memory cell.

14. A memory device comprising:
a normal memory cell configured to be programmable a plurality of number of times;
a one-time programmable (OTP) memory cells configured to be programmable once;
a normal reference cell having a first reference resistance value to distinguish between a parallel state and an anti-parallel state of the normal memory cell;
an OTP reference cell having a second reference resistance value to distinguish between a breakdown state and an anti-parallel state of the OTP memory cell; and
a read circuit configured to read data stored in the normal memory cell based on the first reference resistance value during a read operation of the normal memory cell and read data stored in the OTP memory cell based on the second reference resistance value during a read operation of the OTP memory cell.

15. The memory device of claim 14, wherein, during the read operation of the OTP memory cell, the read circuit is further configured to write the OTP memory cell in the anti-parallel state and then read data stored in the OTP memory cell based on the second reference resistance value.

16. The memory device of claim 14, the read circuit is further configured to:
provide a first electrical signal to the normal memory cell and provide a second electrical signal having a magnitude greater than a magnitude of the first electrical signal to the OTP memory cell; and
read data stored in the normal memory cell based on the first electrical signal and the first reference resistance value and read data stored in the OTP memory cell based on the second electrical signal and the second reference resistance value.

17. The memory device of claim 16, wherein
the first electrical signal comprises a first current and the second electrical signal comprises a second current, and
the read circuit is further configured to
detect a difference between a voltage of the normal memory cell and a voltage of the normal reference cell based on the first current during the read operation of the normal memory cell, and
detect a difference between a voltage of the OTP memory cell and a voltage of the OTP reference cell based on the second current during the read operation of the OTP memory cell.

18. The memory device of claim 16, wherein
the first electrical signal comprises a first voltage and the second electrical signal comprises a second voltage, and
the read circuit is further configured to
detect a difference between a current of the normal memory cell and a current of the normal reference cell based on the first voltage during the read operation of the normal memory cell, and
detect a difference between a current of the OTP memory cell and a current of the OTP reference cell based on the second voltage during the read operation of the OTP memory cell.

19. The memory device of claim 14, wherein a period in which the read operation of the OTP memory cell is performed is longer than a period in which the read operation of the normal memory cell is performed.

20. A method of operating a memory device comprising a normal memory cell configured to be programmable a plurality of number of times and a one-time programmable (OTP) memory cell configured to be programmable once, the method comprising:
during a read operation of the OTP memory cell, writing the OTP memory cell in an anti-parallel state; and
reading data stored in the OTP memory cell based on a resistance value to distinguish between a breakdown state and the anti-parallel state of the OTP memory cell.
